(19) United States
(12) Patent Application Publication
(10) Pub. No.: US 2007/0089014 A1
(43) Pub. Date: Apr. 19, 2007

(54) Semiconductor integrated circuit and method of fabricating the same

(76) Inventors: Takashi Ishimura, Osaka (JP); Kenichiro Uda, Osaka (JP); Yoko Shimada, Kyoto (JP); Katsuya Fujimura, Kyoto (JP); Kasumi Hamaguchi, Osaka (JP); Kenichirou Higashi, Kyoto (JP)

Correspondence Address: MCDERMOTT WILL & EMERY LLP, 600 13TH STREET, N.W., WASHINGTON, DC, 20005-3096, US

(21) Appl. No.: 11/542,271

(22) Filed: Oct. 4, 2006

(30) Foreign Application Priority Data
Oct. 4, 2005 (JP) 2005-291340

(51) Int. Cl. G01R 31/28; G06F 11/00

(52) U.S. Cl. 714/742

(57) ABSTRACT

To provide a semiconductor integrated circuit device in which an occupied area is suppressed from increasing and a high-performance test circuit is included, There is provided a semiconductor integrated circuit having a test circuit, by determining arrangement positions of cells forming a circuit to be tested and non-connected cells prepared to form a test circuit and then determining a connection relationship among the non-connected cells prepared to form the test circuit on the basis of the arrangement information to thereby form the test circuit.

### BACKGROUND OF THE INVENTION

1. Field of the Invention

The present invention relates to a semiconductor integrated circuit and a method of fabricating the same, and in particular, to a technique for wiring arrangement of a semiconductor integrated circuit for the purpose of realization of an easy-to-test design.

2. Description of the Related Art

In recent years, with the development of a technique of making a semiconductor device miniaturized, integrated circuits become highly integrated and complicated. As the integrated circuit becomes large and complicated, the length of a test pattern, which is used to test the integrated circuit after fabricating the integrated circuit, also becomes large, which increases the test cost in manufacturing the integrated circuit.

In order to suppress the test cost from increasing, there is needed a technique of efficiently generating the test pattern by mounting a test circuit within an integrated circuit.

However, if the test circuit is mounted on the integrated circuit, the number of wiring lines within the integrated circuit increases, which makes it difficult to dispose the wiring lines.

In order to solve the problem described above, a technique for improving the wirability by securing a wiring region for test in a macro cell disposed within an integrated circuit is disclosed in Japanese Patent Publication No. 3140103.

Furthermore, in JP-A-8-87538, there is disclosed a technique of suppressing the wiring length of a scan chain by disposing a test circuit for testing a scan path separately from typical circuits.

In the technique disclosed in Patent Document 1, the wirability may be improved; however, since the wiring region for test is prepared within a macro cell, the area of the macro cell becomes uniformly large. As a result, a problem occurs where the area of an integrated circuit becomes large. On the other hand, in the technique disclosed in Patent Document 2, the wiring length of the scan chain may be suppressed; however, it is not possible to reduce the wiring complexity due to a test circuit (for example, a test pattern compression circuit or a built-in self test (BIST) circuit) other than the scan chain.

### SUMMARY OF THE INVENTION

The invention has been finalized in view of the drawbacks inherent in the related art, and it is an object of the invention to provide a semiconductor integrated circuit having a built-in self test function, which is small and has an excellent operation characteristic.

In addition, it is another object of the invention to provide an integrated circuit, which is capable of reducing the wiring complexity when a test circuit is mounted on the integrated circuit, and a method of fabricating the integrated circuit.

According to an aspect of the invention, a method of fabricating a semiconductor integrated circuit includes: a first process of determining arrangement positions onto a substrate with respect to cells forming a circuit to be tested and non-connected cells prepared to form a test circuit; and a second process of determining a connection relationship among the non-connected cells prepared to form the test circuit on the basis of the arrangement position information determined in the first process to thereby form the test circuit.

According to the configuration described above, since a connecting operation is performed after determining the arrangement positions of the cells forming the circuit to be tested and the arrangement positions of the non-connected cells prepared to form the test circuit, those cells can be efficiently disposed. As a result, it is possible to provide a semiconductor integrated circuit having a high-performance test circuit without causing the occupied area to increase.

In the method of fabricating a semiconductor integrated circuit described above, preferably, the first process includes a process in which the arrangement positions of the cells forming the circuit to be tested are determined and then the arrangement positions of the non-connected cells prepared to form the test circuit are determined on the basis of the determined arrangement position information on the circuit to be tested.

According to the configuration described above, since two-step processes are performed in which the arrangement position of the circuit to be tested is determined and then the arrangement position of the test circuit is determined, an efficient arrangement may be made.

Furthermore, in the method of fabricating a semiconductor integrated circuit described above, preferably, the first process includes a process in which the arrangement positions of cells used to form the test circuit are determined, then cells forming the circuit to be tested are arranged, and then the arrangement positions of the non-connected cells prepared to form the test circuit are determined on the basis of the arrangement position information on the circuit to be tested.

According to the configuration described above, since two-step processes are performed in which the arrangement position of the test circuit is determined and then the arrangement position of the circuit to be tested is determined, an efficient arrangement may be made.

Furthermore, in the method of fabricating a semiconductor integrated circuit described above, preferably, a process of rearranging the cells used to form the test circuit is further included.

According to the configuration described above, since an arrangement is once performed and then the cells forming the test circuit are rearranged, it is possible to provide a semiconductor device having an excellent characteristic.

Furthermore, in the method of fabricating a semiconductor integrated circuit described above, preferably, a process of replacing the cells used to form the test circuit with different cells is further included.

According to the configuration described above, due to the cell replacement, it is possible to perform the cell arrangement with good working efficiency.

Furthermore, in the method of fabricating a semiconductor integrated circuit described above, preferably, a process of creating a cell library including a plurality of cells configured such that the width of each of the plurality of cells becomes integral multiples of that of a cell having a smallest width is further included before the first process, and the first process includes a process of selecting cells, which are used to form the test circuit, from the cell library and then arranging the selected cells.

According to the configuration described above, since the library is referred, it is possible to perform the cell arrangement with good working efficiency. In addition, since the cells are configured such that the width of each of the cells becomes integral multiples of that of a cell having a smallest width, the cell replacement can be easily performed.

Moreover, in the method of fabricating a semiconductor integrated circuit described above, preferably, a process of extracting information on a circuit to be tested in which a circuit, which needs to be tested, is selected by using circuit information and then the circuit information on the selected circuit is extracted as information on a circuit to be tested is further included before the first process.

With this configuration described above, since a test circuit may be added to only a required circuit, it is possible to reduce the size of a semiconductor integrated circuit.

Furthermore, in the method of fabricating a semiconductor integrated circuit described above, preferably, a process of determining the types and the number of cells used to form the test circuit on the basis of the information on a circuit to be tested is further included.

Furthermore, in the method of fabricating a semiconductor integrated circuit described above, preferably, a process of securing a region where the cells used to form the test circuit are wired to one another is further included.

Furthermore, in the method of fabricating a semiconductor integrated circuit described above, preferably, a process of using the cells arranged to form the test circuit, which have not been used to form the test circuit, as repair cells is further included.

Furthermore, in the method of fabricating a semiconductor integrated circuit described above, preferably, a process of determining the types and the number of cells used to form the test circuit on the basis of a test method applied to the semiconductor integrated circuit is further included.

Furthermore, in the method of fabricating a semiconductor integrated circuit described above, preferably, a process of identifying the cells forming the circuit to be tested and the cells used to form the test circuit is further included.

Furthermore, in the method of fabricating a semiconductor integrated circuit described above, preferably, a process of creating identification information for identifying the cells forming the circuit to be tested and a process of identifying the cells forming the circuit to be tested and the cells used to form the test circuit by using the identification information are further included.

Furthermore, in the method of fabricating a semiconductor integrated circuit described above, preferably, a process of identifying the cells forming the circuit to be tested and the cells used to form the test circuit on the basis of circuit information is further included.

Furthermore, in the method of fabricating a semiconductor integrated circuit described above, preferably, the first process includes: a process of selecting cells, in which transmission time of signals from an external terminal of the semiconductor integrated circuit is longer than a predetermined threshold value, from the cells forming the circuit to be tested; a first arrangement process of determining arrangement positions of the cells selected from the cells forming the circuit to be tested in the selecting process; and a second arrangement process of determining arrangement positions of the other cells forming the circuit to be tested, which have not been selected in the selecting process, and arrangement positions of the cells used to form the test circuit.

With this configuration described above, it is possible to prevent a test signal from being delayed even if a test circuit is located far away. As a result, it is possible to increase speed and precision of the test.

Further, in the method of fabricating a semiconductor integrated circuit described above, preferably, the second process includes a process of determining a configuration of the test circuit on the basis of the arrangement position information determined in the first arrangement process and the arrangement position information determined in the second arrangement process.

In addition, according to another aspect of the invention, a semiconductor integrated circuit includes a test circuit and a circuit to be tested. Each of the test circuit and the circuit to be tested includes cells, and cells forming the test circuit are disposed in a region where a wiring density between cells forming the circuit to be tested is lower than a predetermined value.

Further, according to another aspect of the invention, a semiconductor integrated circuit includes a test circuit and a circuit to be tested. Each of the test circuit and the circuit to be tested includes cells, and cells forming the circuit to be tested are disposed in a region where a wiring density between cells forming the test circuit is lower than a predetermined value.

In the semiconductor integrated circuit described above, preferably, the test circuit includes the plurality of cells in order to realize a function of the test circuit.

In addition, in the semiconductor integrated circuit described above, preferably, cells, which are connected to one another and used to realize a function of the test circuit, are a plurality of cells configured such that the width of each of the plurality of cells becomes integral multiples of that of a cell having a smallest width.

In addition, in the semiconductor integrated circuit described above, preferably, a combination of a pair of cells, which are used to be connected to each other in order to realize a function of the test circuit, are disposed within a predetermined distance.

In addition, in the semiconductor integrated circuit described above, preferably, the test circuit is formed by using the cells included in the cell library.

In addition, in the semiconductor integrated circuit described above, preferably, a region that is secured in advance is used as a region where the cells forming the test circuit are wired to one another.

As described above, according to the method of the invention, it is possible to reduce the wiring complexity in the case when a test circuit is mounted on a semiconductor integrated circuit. As a result, it is possible to design a small semiconductor integrated circuit with good working efficiency.

In addition, in the invention, it is possible to provide a semiconductor integrated circuit that is small and has a high-performance test circuit.

### BRIEF DESCRIPTION OF THE DRAWINGS

FIG. 1 is an explanatory view illustrating a design flow in a method of fabricating a semiconductor integrated circuit according to a first embodiment of the invention.

FIG. 2 is an explanatory view illustrating a semiconductor integrated circuit according to the first embodiment of the invention.

FIG. 3 is an equivalent circuit diagram illustrating an LFSR (linear feedback shift register).

FIG. 4 is an explanatory view illustrating a design flow in a method of fabricating a semiconductor integrated circuit according to a second embodiment of the invention.

FIG. 5 is a view illustrating a semiconductor integrated circuit obtained by using the method of fabricating a semiconductor integrated circuit shown in FIG. 4.

FIG. 6 is an explanatory view illustrating a design scheme in a method of fabricating a semiconductor integrated circuit according to a third embodiment of the invention.

FIG. 7 is a view illustrating the arrangement of cells of a semiconductor integrated circuit according to the third embodiment.

FIG. 8 is a view illustrating the arrangement of cells of a semiconductor integrated circuit according to the third embodiment.

FIG. 9 is a view illustrating the arrangement of cells of a semiconductor integrated circuit according to the third embodiment.

FIG. 10 is a view illustrating a design scheme in a method of fabricating a semiconductor integrated circuit according to a fourth embodiment.

FIG. 11 is a view illustrating a layout of a semiconductor integrated circuit before performing a process 403 in the method of fabricating a semiconductor integrated circuit shown in FIG. 10.

FIG. 12 is a view illustrating a layout of a semiconductor integrated circuit after performing the process 403 in the method of fabricating a semiconductor integrated circuit shown in FIG. 10.

FIG. 13 is a view illustrating a semiconductor integrated circuit according to a fifth embodiment of the invention.

FIG. 14 is an explanatory view illustrating a design scheme in a method of fabricating a semiconductor integrated circuit according to the fifth embodiment of the invention.

FIG. 15 is an explanatory view illustrating a design scheme in a method of fabricating a semiconductor integrated circuit according to a sixth embodiment of the invention.

FIG. 16 is an explanatory view illustrating a design flow in a method of fabricating a semiconductor integrated circuit according to a seventh embodiment of the invention.

FIG. 17 is an explanatory view illustrating a design scheme in a method of fabricating a semiconductor integrated circuit according to an eight embodiment of the invention.

### DESCRIPTION OF THE PREFERRED EMBODIMENTS

### First Embodiment

A method of fabricating a semiconductor integrated circuit according to a first embodiment of the invention will be described.

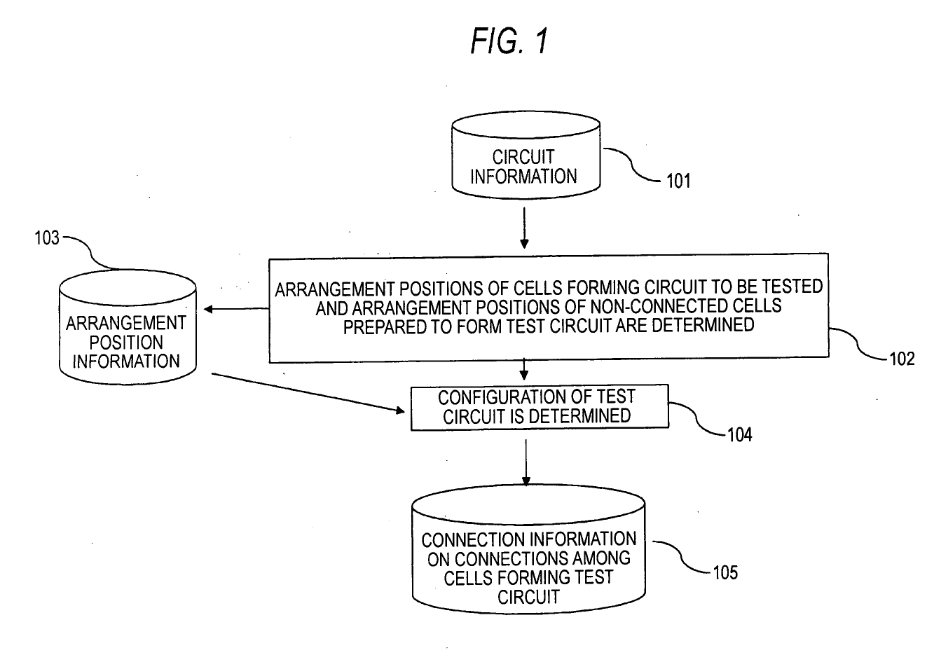

FIG. 1 is a view illustrating a design scheme for a semiconductor integrated circuit in the method of fabricating a semiconductor integrated circuit according to the first embodiment of the invention. This method is characterized in that circuit information is called from database (storage device) in which circuit information 101 is stored, a first process 102, in which arrangement positions onto a substrate with respect to functional cells (hereinafter, referred to as ‘cells’) forming a circuit to be tested and non-connected cells prepared to form a test circuit are determined on the basis of the circuit information, and a second process 104, in which a connection relationship among the non-connected cells prepared to form the test circuit is determined on the basis of arrangement position information 103 determined in the first process 102 and then the test circuit is formed, are included, and connection information 105 on connections among cells forming the test circuit is stored in the database.

That is, in FIG. 1, reference numeral 101 denotes circuit information of a semiconductor integrated circuit. Reference numeral 102 denotes a first process of determining the arrangement positions of cells forming a circuit to be tested and non-connected cells prepared to form a test circuit. Reference numeral 103 denotes arrangement position information on the cells forming the circuit to be tested and non-connected cells prepared to form the test circuit. The arrangement position information 103 is stored in the database. Reference numeral 104 denotes a second process of determining a connection relationship among non-connected cells prepared to form the test circuit to thereby form the test circuit. Reference numeral 105 denotes connection information, which is used to form the test circuit, stored in the database.

Here, the circuit information 101 includes information on a circuit to be tested and information on a test circuit. The information on a circuit to be tested means information on list of cells used to form the circuit to be tested and information on connection among the cells. The information on a test circuit means information on list of non-connected cells prepared to form the test circuit. The above-described information is stored as a gate-level net list in the database.

Further, in the first process 102, the circuit information 101 stored in the database is input, the arrangement positions, which are included in the circuit information 101, of the cells forming the circuit to be tested and the non-connected cells prepared to form the test circuit are determined, and the arrangement positions are output as the arrangement position information 103 to the database. The process may be performed by using EDA tool which is commercially available.

In the arrangement position information 103 stored in the database, physical position information on the cells forming the circuit to be tested and the non-connected cells prepared to form the test circuit is stored as coordinate positions.

In the second process 104, the arrangement position information 103 is input, and then the connection relationship among the non-connected cells prepared to form the test circuit is determined so as to determine connection information for forming the test circuit.

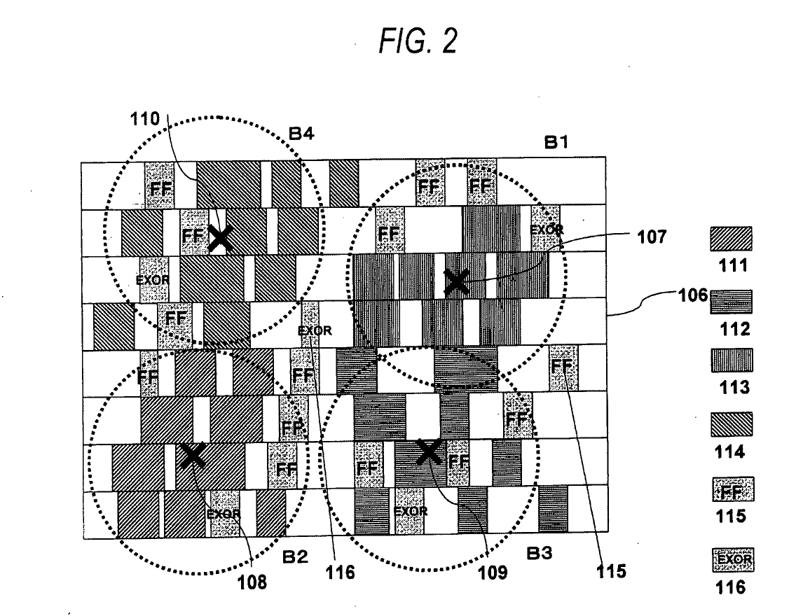

Next, an example of a method of determining the configuration of a test circuit will be described. FIG. 2 illustrates a semiconductor integrated circuit according to the first embodiment of the invention.

Here, a circuit to be tested is divided into four blocks (blocks B1 to B4). In addition, for each block, it is necessary to prepare a linear feedback shift register (hereinafter, referred to as ‘LFSR’) as a test circuit.

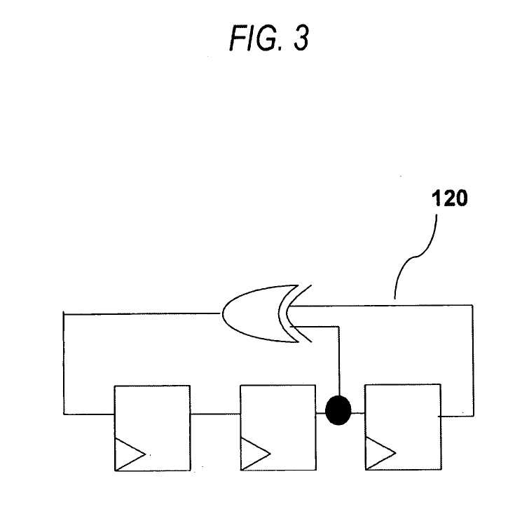

Typically, the LFSR is formed by using a flip-flop (hereinafter, referred to as ‘FF’) and an exclusive OR (hereinafter, referred to as ‘EXOR’). Here, the LFSR is configured as shown by an equivalent circuit in FIG. 3, for the convenience of explanation. That is, a 3-bit LFSR 120 is formed by using three FFs and one XOR. Moreover, in general, an LFSR forming a PRPG (pseudo random pattern generator) used in a logic BIST method, which is used in an actual system LSI, corresponds to 32 bits to several hundred bits. In the second process 104, for example, the configuration of the test circuit is determined as follows. Hereinafter, an explanation will be made with reference to FIG. 2.

First, an average of coordinates indicating positions of cells forming the blocks B1 to B4 is obtained and center coordinates 107 to 110 of the blocks are obtained. Here, reference numeral 106 denotes a view illustrating a layout in a case in which cells forming the circuit to be tested and non-connected cells prepared to form the test circuit are arranged. Cells denoted by reference numeral 111 are cells forming the block B1. Cells denoted by reference numeral 112 are cells forming the block B2. cells denoted by reference numeral 113 are cells forming the block B3. Cells denoted by reference numeral 114 are cells forming the block B4. Reference numerals 107, 108, 109, and 110 denote center coordinates each of which is an average of coordinates indicating positions of the cells forming each block.

Then, three FFs and one EXOR which are closest to the center coordinate are selected for each block. Thereafter, the configuration of the LFSR circuit is determined by using the selected FFs and EXOR. Cells denoted by reference numeral 115 are FFs among the non-connected cells prepared to form the test circuit. Cells denoted by reference numeral 116 are EXORs among the non-connected cells prepared to form the test circuit.

Then, three FFs and one EXOR which are closest to the center coordinate are selected for each of the blocks 111 to 114. Specifically, the three FFs and one EXOR are the cells 115 and the cell 116 selected for each of the blocks 111 to 114, which are included inside a circle that has each coordinate 107, 108, 109, or 110 corresponding to a center and is indicated by a dotted line.

The LFSR 120 is formed by using the selected three FFs and one EXOR. As shown by the equivalent circuit in FIG. 3, information indicating connection relationship among the cells forming the LFSR 120 corresponds to the connection information 105 used to form the test circuit.

In addition, the cells 115 and 115, which are not included inside the circle that has each of the coordinates 107 to 110 corresponding to a center and is indicated by the dotted line, are not used to form the test circuit. These cells may be placed within a circuit so as to be effectively used as repair cells.

### Second Embodiment

A method of fabricating a semiconductor integrated circuit according to a second embodiment of the invention will be described.

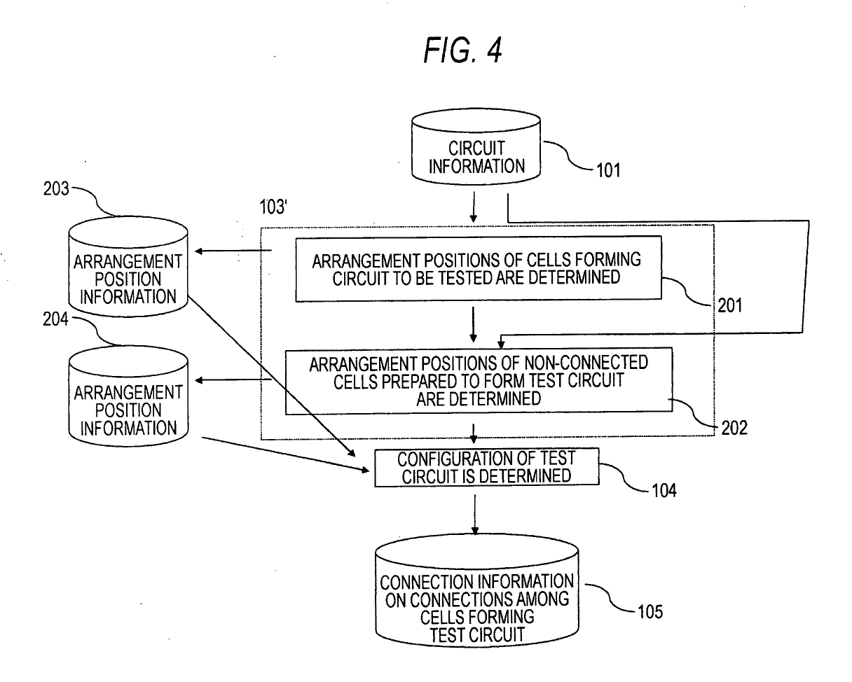

FIG. 4 is a view illustrating a design scheme for a semiconductor integrated circuit in the method of fabricating a semiconductor integrated circuit according to the second embodiment of the invention. In the method, instead of the first process 102 described in the first embodiment, there is included a process 201 in which arrangement positions of cells forming a circuit to be tested are determined and a process 202 in which arrangement positions of non-connected cells prepared to form a test circuit are determined on the basis of determined arrangement position information 203 on the circuit to be tested, as is surrounded by a dotted line 103′.

In FIG. 4, reference numeral 101 denotes circuit information on the semiconductor integrated circuit described in the first embodiment. Reference numeral 201 denotes a process of determining arrangement positions of cells forming the circuit to be tested. Reference numeral 202 denotes a process of determining arrangement positions of non-connected cells prepared to form the test circuit. Reference numeral 203 denotes arrangement position information on the cells forming the circuit to be tested, and reference numeral 204 denotes arrangement position information on the non-connected cells prepared to form the test circuit. Reference numeral 104 denotes a process of determining a connection relationship among non-connected cells prepared to form the test circuit and then forming the test circuit, which has been described in the first embodiment. Reference numeral 105 denotes connection information for forming the test circuit, which has been described in the first embodiment.

In the process 201 of determining the arrangement positions of the cells forming the circuit to be tested, circuit information 101 is input, the arrangement positions of the cells forming the circuit to be tested are determined, and then arrangement position information 203 is output. In the process 102 of determining the arrangement positions of the non-connected cells prepared to form the test circuit, the circuit information 101 is input, the arrangement positions of the non-connected cells prepared to form the test circuit, which are included in the circuit information 101, are determined, and then arrangement position information 204 is output. These processes may be performed by using EDA tool which is commercially available.

Physical position information on the cells forming the circuit to be tested is stored as coordinate positions in the arrangement position information 203. Physical position information on the non-connected cells prepared to form the test circuit is stored as coordinate positions in the arrangement position information 204.

In a second process 104, the arrangement position information 203 and the arrangement position information 204 are input, the connection relationship among the non-connected cells prepared to form the test circuit is determined, and the connection information 105 used to form the test circuit is determined to be then output.

The second embodiment is different from the first embodiment in that the process 201 of determining the arrangement positions, which are included in the circuit information 101, of the cells forming the circuit to be tested, and the process 202 of determining the arrangement positions, which are included in the circuit information 101, of the non-connected cells prepared to form the test circuit are sequentially and separately performed. By performing the process 201 before the process 202, the non-connected cells prepared to form the test circuit can be disposed in an empty space. As a result, it is possible to improve the timing of the circuit to be tested and not to have an effect on the wiring density without causing disposition of the circuit to be tested to be complicated.

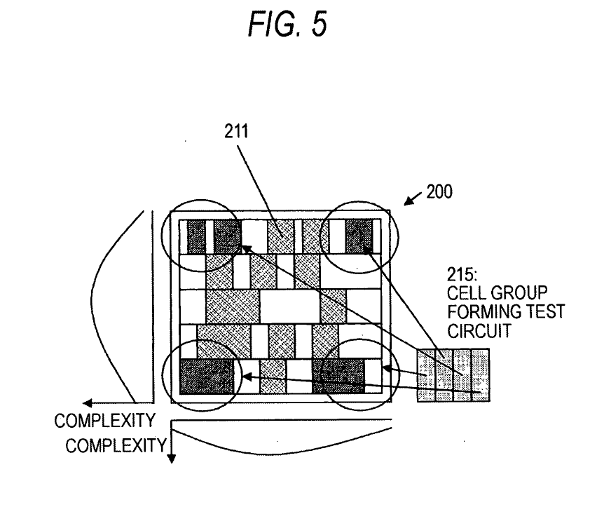

FIG. 5 illustrates a semiconductor integrated circuit according to the second embodiment. A circuit shown in FIG. 5 is a semiconductor integrated circuit obtained by using the method of fabricating a semiconductor integrated circuit shown in FIG. 4. The complexity due to arrangement of cells 211 forming a circuit to be tested is shown at a lower side and a left side of a chip 200. As is apparent from FIG. 5, by disposing a non-connected cell group 215 forming a test circuit in a region where the number of wiring lines per unit between cells 211 forming a circuit to be tested is smaller than a predetermined value, that is, a region where the complexity is low, it is possible to improve the timing of the circuit to be tested and to obtain a semiconductor integrated circuit having a test circuit without having an effect on the wiring density.

### Third Embodiment

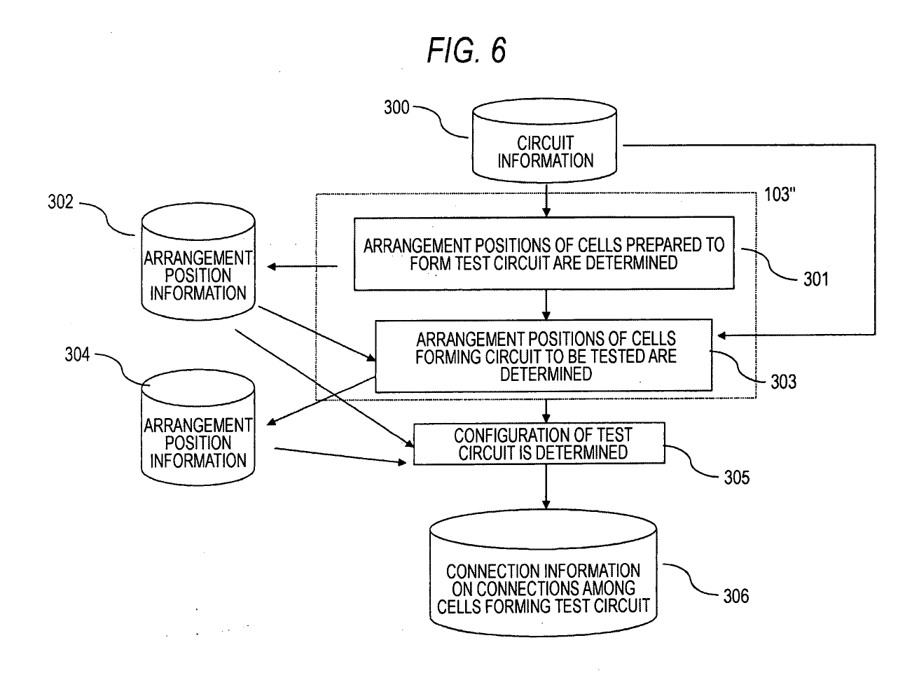

Next, a third embodiment of the invention will be described. FIG. 6 is a view illustrating a design scheme for a semiconductor integrated circuit in a method of fabricating a semiconductor integrated circuit according to the third embodiment of the invention. In the method, instead of the first process 102 described in the first embodiment, there is included a process 301 in which arrangement positions of non-connected cells prepared to form a test circuit are determined and a process 303 in which arrangement positions of cells forming a circuit to be tested are determined on the basis of determined arrangement position information 302 on the test circuit, as is surrounded by a dotted line 103″. In addition, the method includes a process 305 in which the arrangement positions of the non-connected cells prepared to form the test circuit are determined on the basis of determined arrangement position information 304 on the circuit to be tested and the arrangement position information 302 on the test circuit.

In FIG. 6, reference numeral 300 denotes circuit information of the semiconductor integrated circuit according to the present embodiment. Reference numeral 301 denotes a first process of determining arrangement positions of cells forming a test circuit. Reference numeral 302 denotes arrangement position information on the cells forming the test circuit. Reference numeral 303 denotes a second process of determining arrangement positions of cells forming a circuit to be tested by using the arrangement position information on the cells forming the test circuit. Reference numeral 304 denotes arrangement position information on the cells forming the circuit to be tested. Reference numeral 305 denotes a process of determining the configuration of the test circuit by using the arrangement position information 302 and the arrangement position information 304. Reference numeral 306 denotes connection information for connection of the test circuit.

The circuit information 300 includes information on the circuit to be tested and information on the test circuit. The information on the circuit to be tested means information on list of cells used to form the circuit to be tested and information on connection among the cells. The information on the test circuit means information on list of non-connected cells prepared to form the circuit to be tested. The above-described information is stored as a gate-level net list in a storage device.

In the process 301, the circuit information 300 is input, the arrangement positions of the non-connected cells prepared to form the test circuit, which are included in the circuit information 300, are determined, and then the arrangement position information 302 is output.

Physical position information on the non-connected cells prepared to form the test circuit is stored as coordinate positions in the arrangement position information 302.

In the process 303, the circuit information 300 and the arrangement position information 302 are input, the arrangement positions of the cells forming the circuit to be tested, which are included in the circuit information 300, are determined, and then the arrangement position information 304 is output.

Physical position information on the cells forming the circuit to be tested is stored as coordinate positions in the arrangement position information 304.

In the process 305, the arrangement position information 302 and the arrangement position information 304 are input, connection relationship among the non-connected cells prepared to form the test circuit is determined, and the connection information 306 on the cells forming the test circuit is output.

Next, an example of a method of determining the configuration of a test circuit will be described.

Here, the configuration of the circuit to be tested and the configuration of the test circuit are the same as the configuration of the cells described in the first embodiment.

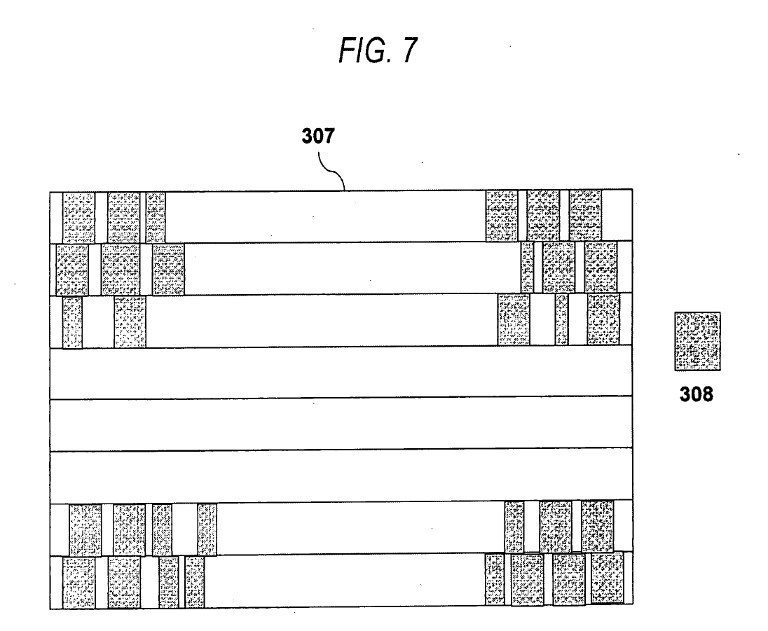

First, in the process 301, for example, as shown in FIG. 7, it is possible to determine the arrangement positions of cells used to form the test circuit. An example of the arrangement positions is shown in FIG. 7, and it is possible for a designer to arbitrarily determine the arrangement positions in consideration of connection among circuits, a connection between a test circuit and IO cells, or the like. Reference numeral 307 indicates an example of a layout in a case in which non-connected cells used to form the test circuit are disposed. Reference numeral 308 denotes a non-connected cell used to form the test circuit.

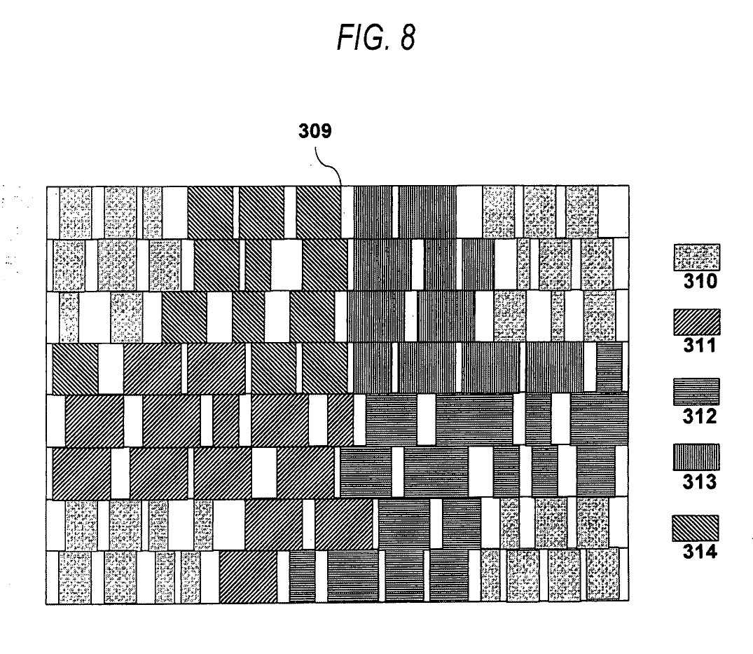

Then, in the process 303, for example, as shown in FIG. 8, cells forming the circuit to be tested are disposed in a region excluding arrangement positions of the cells used to form the test circuit, which have been determined in the process 301. An example of the arrangement positions is shown in FIG. 8, and it is possible for a designer to arbitrarily determine the arrangement positions in consideration of connectability between the test circuit and the circuit to be tested. Reference numeral 309 indicates an example of a layout in a case in which non-connected cells used to form the test circuit and cells forming the circuit to be tested are disposed. Reference numeral 310 indicates a non-connected cell used to form the test circuit. Reference numerals 311 to 314 denote cells forming the blocks B1 to B4, respectively.

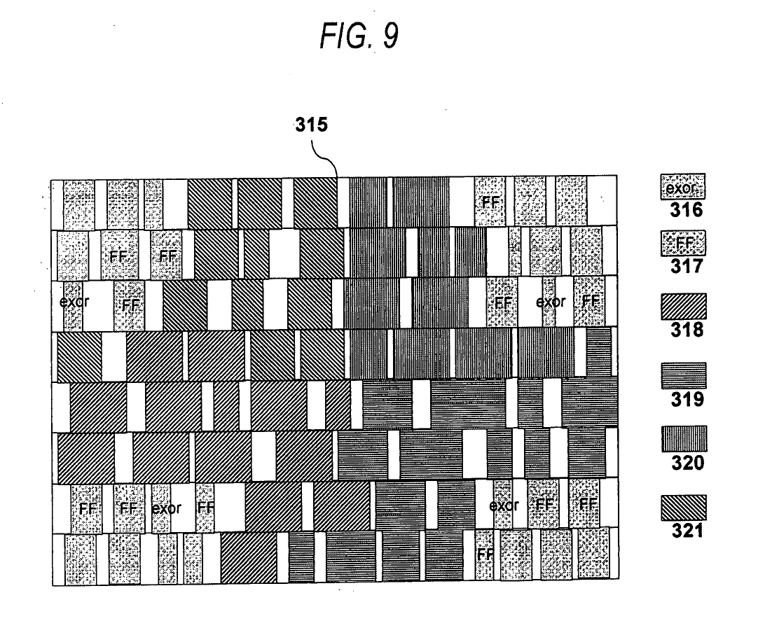

Then, in the process 305, for example, as shown in FIG. 9, the LFSR 120 for each block is formed by using the arrangement position information on the cells forming the test circuit and the arrangement position information on the cells forming the circuit to be tested, which have been determined in the processes 301 and 303. Information indicating connection relationship of cells forming the LFSR 120 is the connection information 306 for forming the test circuit shown in FIG. 6. Reference numeral 315 denotes a view illustrating a layout in a case in which cells forming the circuit to be tested and cells prepared to form the test circuit are arranged so as to be connected to one another by using the arrangement position information 302 and 304. Reference numeral 316 denotes a cell, which performs an EXOR logic operation, among the cells forming the test circuit. Reference numeral 317 denotes a cell, which performs a flip-flop function, among the cells forming the test circuit. Reference numerals 318 to 321 denote cells forming the blocks B1 to B4, respectively.

### Fourth Embodiment

A method of fabricating a semiconductor integrated circuit according to a fourth embodiment of the invention will be described.

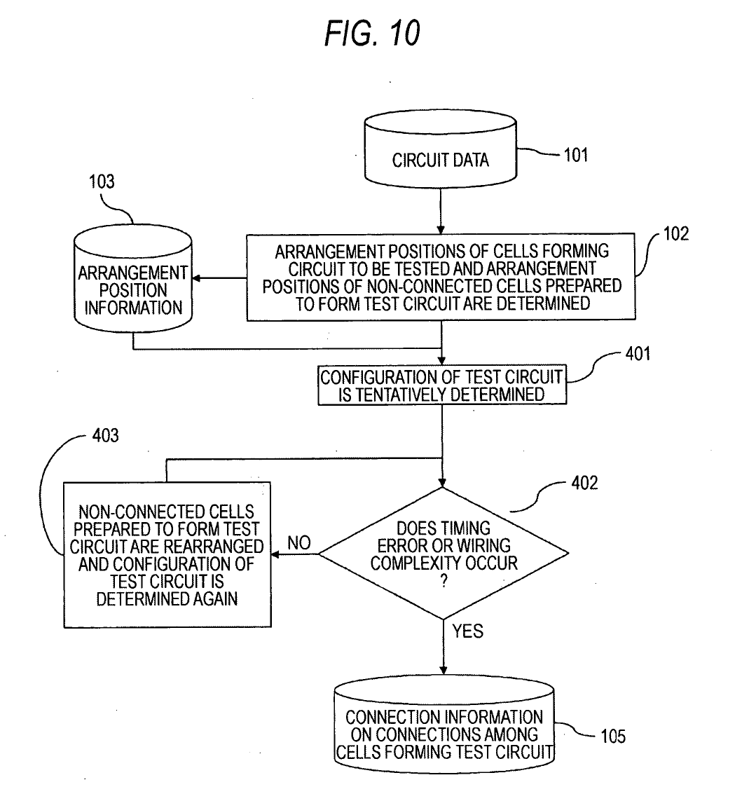

FIG. 10 is a view illustrating a design scheme for a semiconductor integrated circuit in a method of fabricating a semiconductor integrated circuit according to the fourth embodiment of the invention. In the present embodiment, instead of the process 104 of determining the configuration of the test circuit in the first embodiment, a process 401 of tentatively determining the configuration of a test circuit is performed. After the tentative determination process 401, it is determined whether or not timing error or wiring complexity occurs in a determination process 402. If it is determined that the timing error or the wiring complexity does not occur, the connection information 105 on cells forming a test circuit is obtained. On the other hand, if it is determined that the timing error or the wiring complexity occurs, the non-connected cells prepared to form the test circuit are rearranged, the configuration of the test circuit is determined again in a process 403, and then the process returns to the determination process 402 by means of a loop so as to verify the timing error or the wiring complexity.

Reference numeral 401 denotes a process of tentatively determining of connection relationship among the non-connected cells prepared to form the test circuit. Reference numeral 402 denotes a process of determining whether or not the timing error or the wiring complexity has occurred by performing timing calculation or wiring complexity estimation on the basis of the connection information on the test circuit that is tentatively determined. Reference numeral 403 denotes a process of determining the configuration of the test circuit by rearranging the non-connected cells in a place determined that the timing error occurs or the wiring complexity occurs in the determination process 402.

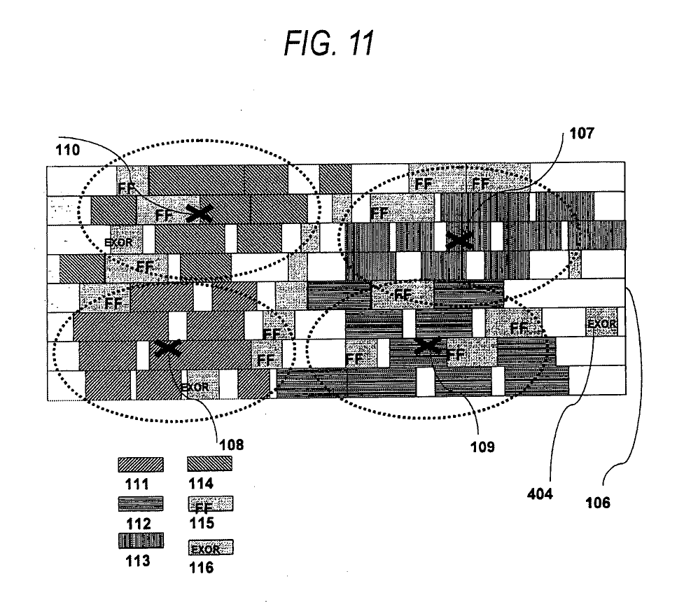

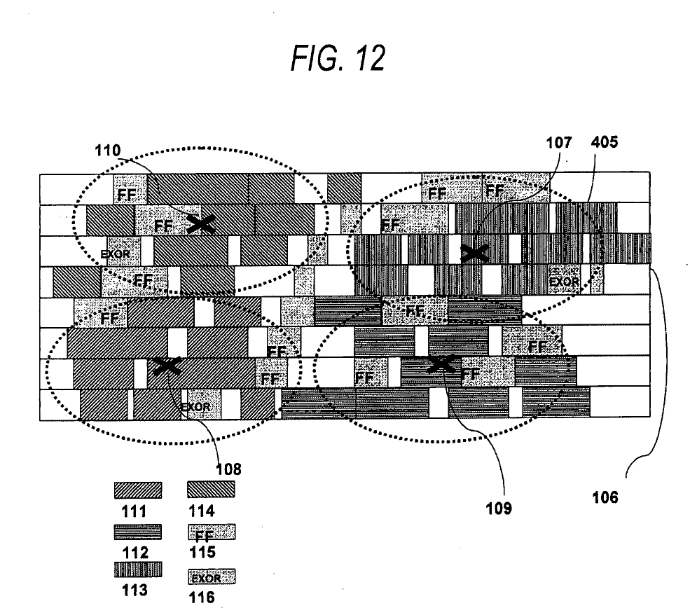

FIG. 11 is a view illustrating a layout of a semiconductor integrated circuit before performing the process 403 shown in FIG. 10, in which the method of fabricating a semi-conductor integrated circuit is determined again. FIG. 12 is a view illustrating a layout of a semiconductor integrated circuit after performing the process 403 shown in FIG. 10, in which the method of fabricating a semiconductor integrated circuit is determined again.

Reference numeral 404 denotes a coordinate at which an EXOR closest to the coordinate 107 exists, and reference numeral 405 denotes a coordinate in which the timing error does not occur in the case where the LFSR 120 is configured such that a cell corresponding to the coordinate denoted by reference numeral 405 is connected to a cell 115 included inside a circle, which has a center corresponding to the coordinate 107 and is indicated by a dotted line.

As described above, the semiconductor integrated circuit and the method of fabricating a semiconductor integrated circuit according to the present embodiment is different from those in the first embodiment in that the connection relationship among the non-connected cells prepared to form the test circuit 101 is determined and then the non-connected cells are rearranged so that the timing error or the wiring complexity does not occur in the process 104 of forming the test circuit.

According to the present embodiment, in the case in which the cell 116 included inside a circle, which has a center corresponding to the coordinate 107 and is indicated by the dotted line, does not exist, an EXOR existing at a closest coordinate is located at the coordinate 404, and timing error occurs, it is possible to eliminate the timing error by rearranging an EXOR existing at the coordinate 404 at the coordinate 405.

Furthermore, in the present embodiment, in the case when the cell 116 included inside a circle, which has a center corresponding to the coordinate 107 and is indicated by the dotted line, does not exist, it may be possible to prevent the timing error and the wiring complexity by changing different kinds of non-connected cells included inside the circle, which has a center corresponding to the coordinate 107 and is indicated by the dotted line, to the cell 116 without performing a rearranging operation on the cells

### Fifth Embodiment

A method of fabricating a semiconductor integrated circuit according to a fifth embodiment of the invention will be described.

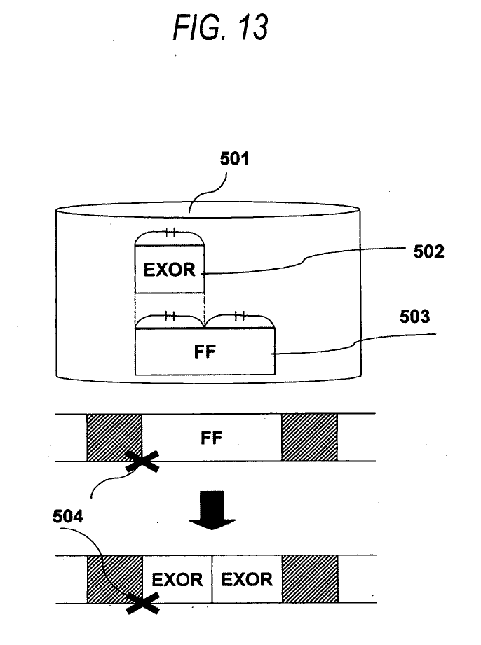

FIG. 13 is a view illustrating a library for forming the semiconductor integrated circuit according to the fifth embodiment of the invention. Reference numeral 501 denotes a library for non-connected cells forming the test circuit. Reference numeral 502 denotes an EXOR cell included in the library 501. Reference numeral 503 denotes an FF cell included in the library 501. In addition, reference numeral 504 denotes coordinates at which non-connected cells forming a test circuit are disposed. In the present embodiment, all of the cells forming a test circuit are configured such that the width of each of the cells becomes integral multiples of that of a cell having a smallest width. As is apparent from FIG. 13, the width of the FF 503 is twice (integral multiples) larger than that of the EXOR cell 502 having a smallest width.

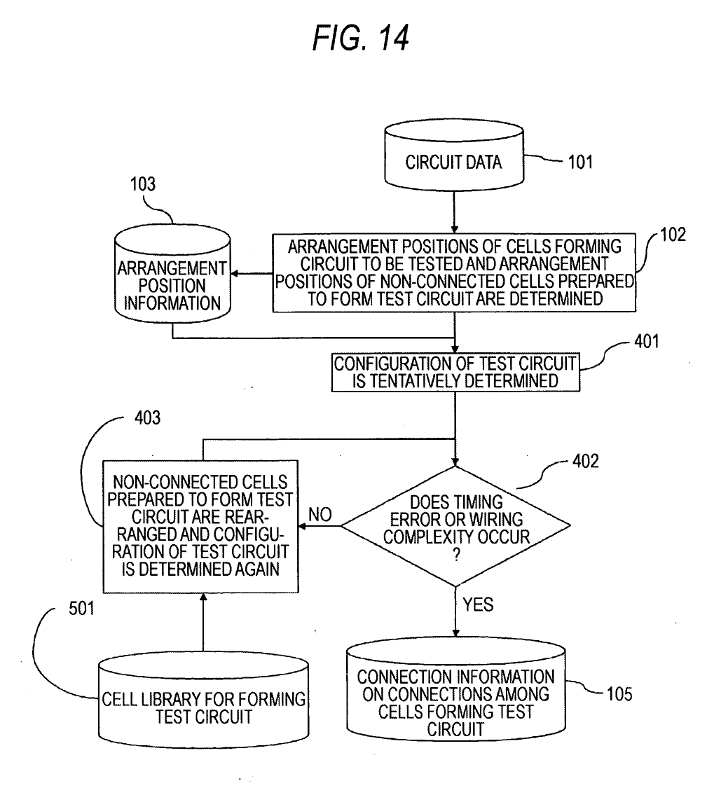

The present embodiment is characterized in that the cell library 501 is added, as can be seen from a method of fabricating a semiconductor integrated circuit shown in FIG. 14. Specifically, in the present embodiment, if it is determined that the timing error or the wiring complexity occurs, an operation of replacing a cell and an operation of rearranging the non-connected cells prepared to form the test circuit are performed by using the cell library 501, the configuration of the test circuit is determined again in the process 403, and then the process returns to the determination process 402 by means of a loop so as to verify the timing error or the wiring complexity and to perform a replacement operation.

Here, the EXOR 502 is a cell having a smallest width among cells included in the library 501. The width of the FF 503 is twice (integral multiples) larger than that of the EXOR cell 502 having a smallest width.

By using the library 501, it is possible to dispose two EXORs 502 at the coordinate 504 of the FF when performing the cell rearranging operation and the cell exchanging operation in the fourth embodiment, even in the case of a circuit having a high spreading rate. As a result, it is possible to efficiently perform the cell rearranging operation and the cell exchanging operation. Further, since all cells are configured such that the width of each of the cells becomes integral multiples of that of a cell having a smallest width, the replacement becomes very easy. As a result, a layout operation can be performed with good working efficiency.

### Sixth Embodiment

Next, a method of fabricating a semiconductor integrated circuit according to a sixth embodiment of the invention will be described.

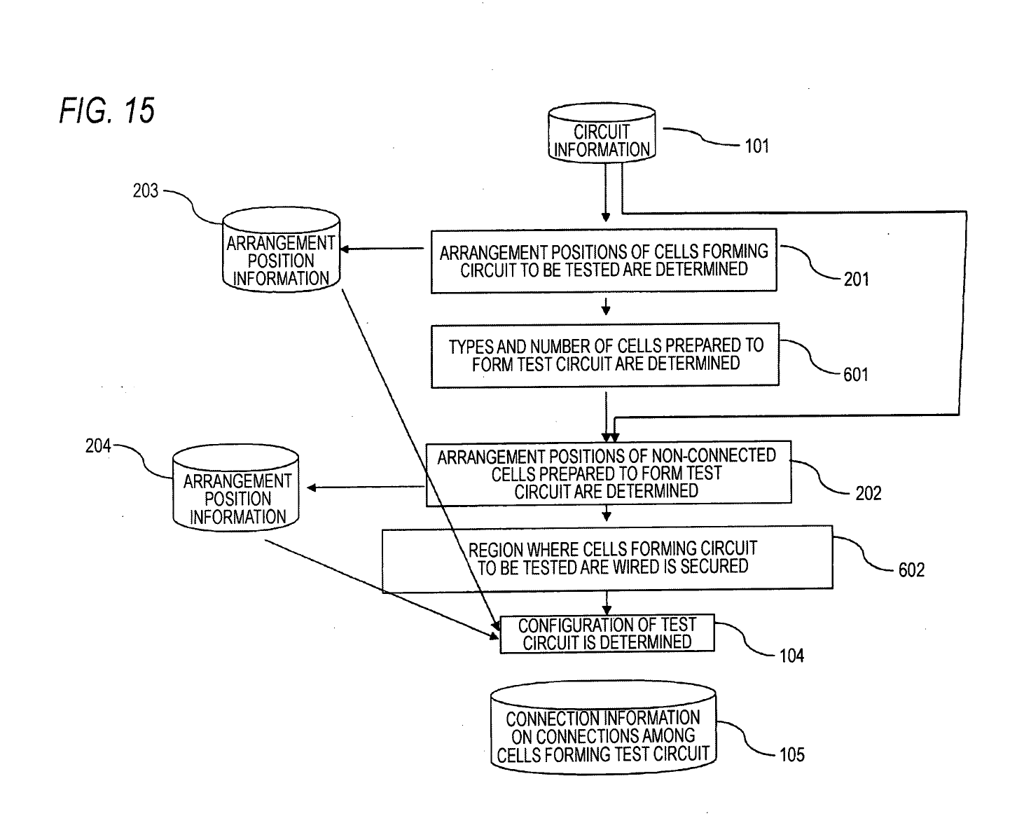

FIG. 15 is a view illustrating a design scheme in the method of fabricating a semiconductor integrated circuit according to the sixth embodiment of the invention. The present embodiment is characterized in that a process 601 of determining the types and the number of cells prepared to form a test circuit before the process 202 of determining the arrangement positions of non-connected cells forming the test circuit and a process 602 of securing a region where cells forming a circuit to be tested are wired to one another before the process 104 of determining the configuration of the test circuit are included.

As described above, in FIG. 15, reference numeral 601 denotes a process of determining the types and the number of cells prepared to form the test circuit. Reference numeral 602 denotes a process of securing a region for wiring lines beforehand after connecting the non-connected cells used to form the test circuit.

In the above-described method according to the present embodiment, by adding the process 601 in which the types and the number of cells prepared to form the test circuit are determined, the types and the number of cells that are required are estimated in advance on the basis of circuit information or selected DFT (design for test) information, and then the non-connected cells are arranged according to a result of the estimation. As a result, it is possible to prevent unnecessary cell from being used, which makes it possible to reduce the chip cost.

In addition, by adding the process 602 of securing a region where cells forming a circuit to be tested are wired to one another, it is possible to a wiring region for a test circuit in advance. As a result, it is possible to prevent wiring lines of a test circuit from being extremely lengthening, regardless of a wiring result of the circuit to be tested.

### Seventh Embodiment

Next, a method of fabricating a semiconductor integrated circuit according to a seventh embodiment of the invention will be described.

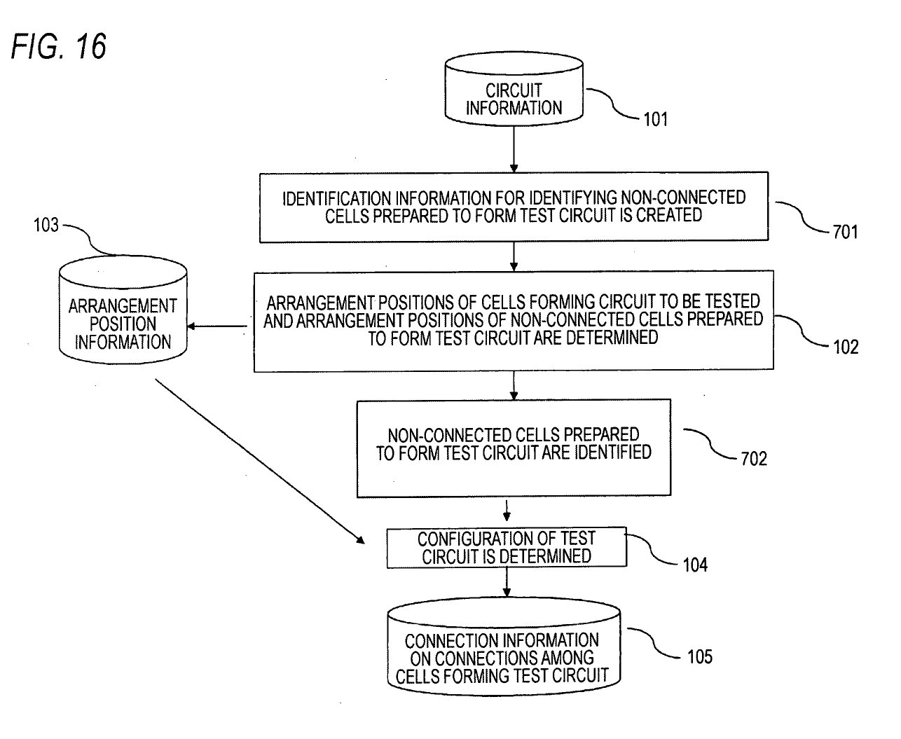

FIG. 16 is a view illustrating a design scheme in the method of fabricating a semiconductor integrated circuit according to the seventh embodiment of the invention. The design scheme is characterized in that a process 701 of creating identification information is added before the first process 102 of the design scheme shown in FIG. 1 and a process 702 of identifying cells forming a test circuit is added before the second process 104 of determining the configuration of the test circuit after the first process 102. In the present embodiment, prior to the first process 102 in the first embodiment in which the arrangement positions of the cells forming the circuit to be tested and the arrangement positions of the non-connected cells prepared to form the test circuit are determined, the process 701 of creating identification information for identifying the non-connected cells prepared to form the test circuit is first performed. After performing the first process 102, the process 702 of identifying the non-connected cells prepared to form the test circuit is performed on the basis of the identification information created in the process 701 of creating the identification information. Then, the second process 104 of determining the configuration of the test circuit is performed.

Reference numeral 701 denotes a process of creating information for identifying the non-connected cells prepared to form the test circuit. Reference numeral 702 denotes a process of identifying the non-connected cells prepared to form the test circuit.

The circuit information 101 is stored as a gate-level net list in a storage device. Within the net list, a plurality of cells (instances) forming the circuit to be tested and a plurality of non-connected cells (instances) prepared to form the test circuit are included together. In the case when the cells forming the circuit to be tested and the non-connected cells prepared to form the test circuit cannot be distinguished from each other, the test circuit cannot be formed in the second process 104. Accordingly, in this case, it is necessary that information for identifying the non-connected cells prepared to form the test circuit be added in the net list in the process 701 of creating the identification information, the non-connected cells prepared to form the test circuit be identified in the identification process 702 by using the information added in the process 701, and the test circuit be formed in the second process 104. By adding a proper identifier to a cell name (instance name) and listing up cell names, it is possible to identify cells on the basis of the list.

### Eighth Embodiment

A method of fabricating a semiconductor integrated circuit according to an eighth embodiment of the invention will be described.

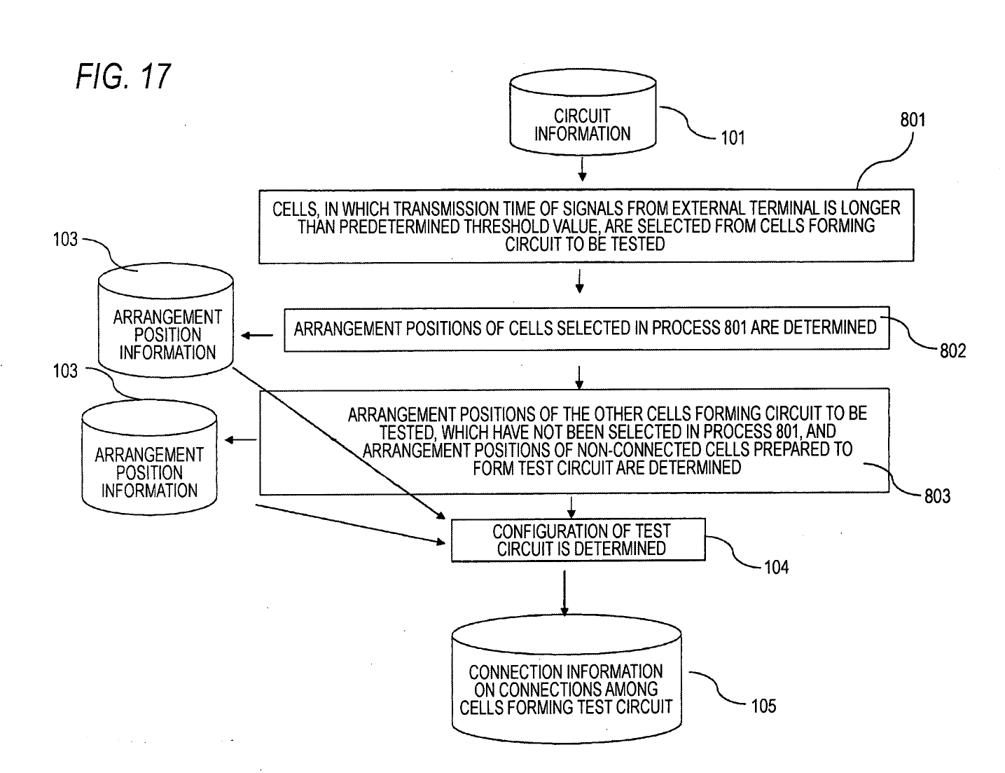

FIG. 17 is a view illustrating a design scheme in the method of fabricating a semiconductor integrated circuit according to the eighth embodiment of the invention. The present embodiment is characterized in that cells forming a circuit to be tested are classified on the basis of transmission time of signals from an external terminal, the arrangement positions of cells having long signal transmission time are first determined, and then the arrangement positions of cells having short signal transmission time are determined. Specifically, a process 801 of selecting cells, in which transmission time of signals from an external terminal is longer than a predetermined threshold value, from the cells forming the circuit to be tested is added, then a process 802 of determining the arrangement positions of cells having signal transmission time longer than the predetermined threshold value, which have been selected in the process 801, is first performed, and then a process 803 of determining the arrangement positions of the other cells.

In FIG. 17, reference numeral 801 denotes a process of selecting cells, in which transmission time of signals from an external terminal is longer than a predetermined threshold value, from the cells forming the circuit to be tested. Reference numeral 802 denotes a process of determining the arrangement positions of the cells selected in the process 801. Reference numeral 803 denotes a process of determining the arrangement positions of the other cells forming the circuit to be tested, which have not been selected in the process 801, and the arrangement positions of the non-connected cells prepared to form the test circuit.

In an IF part interfaced with an external terminal, it is necessary to preferentially dispose cells, which are located on a path through which data needs to be transmitted to an internal register at high speed, in the periphery of a chip. In the method of fabricating a semiconductor integrated circuit according to the eighth embodiment, since the cells located on a path through which data is transmitted from/to an external terminal are preferentially disposed in the periphery of a chip, it is possible to make a design such that AC timing of IO peripheral circuits can be satisfied.

In the method of fabricating a semiconductor integrated circuit and the semiconductor integrated circuit formed by using the method according to the embodiments of the invention, it is possible to reduce the wiring complexity in the case when the test circuit is mounted on the semiconductor integrated circuit.

What is claimed is:

1. A method of fabricating a semiconductor integrated circuit comprising:
a first process of determining arrangement positions onto a substrate with respect to cells forming a circuit to be tested and non-connected cells prepared to form a test circuit; and
a second process of determining a connection relationship among the non-connected cells prepared to form the test circuit on the basis of the arrangement position information determined in the first process to thereby form the test circuit.

2. The method of fabricating a semiconductor integrated circuit according to claim 1,
wherein the first process includes a process in which the arrangement positions of the cells forming the circuit to be tested are determined and then the arrangement positions of the non-connected cells prepared to form the test circuit are determined on the basis of the determined arrangement position information on the circuit to be tested.

3. The method of fabricating a semiconductor integrated circuit according to claim 1,
wherein the first process includes a process in which the arrangement positions of cells used to form the test circuit are determined, then cells forming the circuit to be tested are arranged, and then the arrangement positions of the non-connected cells prepared to form the test circuit are determined on the basis of the arrangement position information on the circuit to be tested.

4. The method of fabricating a semiconductor integrated circuit according to claim 1, further comprising:
a process of rearranging the cells used to form the test circuit.

5. The method of fabricating a semiconductor integrated circuit according to claim 1, further comprising:
a process of replacing the cells used to form the test circuit with different cells.

6. The method of fabricating a semiconductor integrated circuit according to claim 1, further comprising:
a process of creating a cell library including a plurality of cells configured such that the width of each of the plurality of cells becomes integral multiples of that of a cell having a smallest width, prior to the first process,
wherein the first process includes a process of selecting cells, which are used to form the test circuit, from the cell library and then arranging the selected cells.

7. The method of fabricating a semiconductor integrated circuit according to claim 6, further comprising:
a process of extracting information on a circuit to be tested in which a circuit, which needs to be tested, is selected by using circuit information and then the circuit information on the selected circuit is extracted as information on a circuit to be tested, prior to the first process.

8. The method of fabricating a semiconductor integrated circuit according to claim 7, further comprising:
a process of determining the types and the number of cells used to form the test circuit on the basis of the information on a circuit to be tested.

9. The method of fabricating a semiconductor integrated circuit according to claim 1, further comprising:
a process of securing a region where the cells used to form the test circuit are wired to one another.

10. The method of fabricating a semiconductor integrated circuit according to claim 1, further comprising:
a process of using the cells arranged to form the test circuit, which have not been used to form the test circuit, as repair cells.

11. The method of fabricating a semiconductor integrated circuit according to claim 1, further comprising:
a process of determining the types and the number of cells used to form the test circuit on the basis of a test method applied to the semiconductor integrated circuit.

12. The method of fabricating a semiconductor integrated circuit according to claim 1, further comprising:
a process of identifying the cells forming the circuit to be tested and the cells used to form the test circuit.

13. The method of fabricating a semiconductor integrated circuit according to claim 12, further comprising:
a process of creating identification information for identifying the cells forming the circuit to be tested; and
a process of identifying the cells forming the circuit to be tested and the cells used to form the test circuit by using the identification information.

14. The method of fabricating a semiconductor integrated circuit according to claim 13, further comprising:
a process of identifying the cells forming the circuit to be tested and the cells used to form the test circuit on the basis of circuit information.

15. The method of fabricating a semiconductor integrated circuit according to claim 1,
wherein the first process includes: a process of selecting cells, in which transmission time of signals from an external terminal of the semiconductor integrated circuit is longer than a predetermined threshold value, from the cells forming the circuit to be tested;
a first arrangement process of determining arrangement positions of the cells selected from the cells forming the circuit to be tested in the selecting process; and
a second arrangement process of determining arrangement positions of the other cells forming the circuit to be tested, which have not been selected in the selecting process, and arrangement positions of the cells used to form the test circuit.

16. The method of fabricating a semiconductor integrated circuit according to claim 15,
wherein the second process is a process of determining a configuration of the test circuit on the basis of the arrangement position information determined in the first arrangement process and the arrangement position information determined in the second arrangement process.

17. A semiconductor integrated circuit comprising:
a test circuit; and
a circuit to be tested,
wherein each of the test circuit and the circuit to be tested includes cells, and
cells forming the test circuit are disposed in a region where a wiring density between cells forming the circuit to be tested is lower than a predetermined value.

18. A semiconductor integrated circuit comprising:
a test circuit; and
a circuit to be tested,
wherein each of the test circuit and the circuit to be tested includes cells, and
cells forming the circuit to be tested are disposed in a region where a wiring density between cells forming the test circuit is lower than a predetermined value.

19. The semiconductor integrated circuit according to claim 17,
wherein the test circuit includes the plurality of cells in order to realize a function of the test circuit.

20. The semiconductor integrated circuit according to claim 18,
wherein the test circuit includes the plurality of cells in order to realize a function of the test circuit.

21. The semiconductor integrated circuit according to claim 17,
wherein cells, which are connected to one another and used to realize a function of the test circuit, are a plurality of cells configured such that the width of each of the plurality of cells becomes integral multiples of that of a cell having a smallest width.

22. The semiconductor integrated circuit according to claim 18,
wherein cells, which are connected to one another and used to realize a function of the test circuit, are a plurality of cells configured such that the width of each of the plurality of cells becomes integral multiples of that of a cell having a smallest width.
